(19) United States
(12) Patent Application Publication
(10) Pub. No.: US 2009/0015263 A1
(43) Pub. Date: Jan. 15, 2009

(54) Ion Control Sensor

(75) Inventor: Yomatsu Nakajima, Tokyo (JP)

Correspondence Address: BIRCH STEWART KOLASCH & BIRCH, PO BOX 747, FALLS CHURCH, VA, 22040-0747, US

(73) Assignee: HUGLE ELECTRONICS INC., Tokyo (JP)

(21) Appl. No.: 11/886,692

(22) PCT Filed: Jun. 13, 2005
(86) PCT No.: PCT/JP2005/011195

§ 371 Date: Sep. 19, 2007

(30) Foreign Application Priority Data
May 27, 2005 (JP) 2005-155348

(51) Int. Cl. G01R 29/12

(52) U.S. Cl. 324/457

(57) ABSTRACT

A static electricity removal device that removes static electricity by supplying positive and negative ions to a target of static electricity removal, comprising a surface potential measuring probe that measures a surface potential of the target of static electricity removal, wherein a potential detector (11a) that constitutes a surface potential measuring probe (11) and a conductive cap (13) placed so as to surround the potential detector (11a) in a non-contact state are provided and a potential generated in the cap (13) by charges of a target of static electricity removal (30) or ions supplied from a static electricity removal device (20) is detected by the potential detector (11a) and sent out to a control circuit (24) within the static electricity removal device (20) as a feedback signal. According to the present invention, a remarkably simple configuration makes it possible to detect an ion balance and a charged potential of the target of static electricity removal, thereby contributing to improvement in static electricity removal performance of an ionizer.

### TECHNICAL FIELD

The present invention relates to an ion control sensor that can detect both an ion balance between the numbers of positive and negative ions generated by a static electricity removal device and a charged potential of a target of static electricity removal.

### BACKGROUND ART

Conventionally, a static electricity removal device that variably controls a voltage to be applied to a discharge electrode needle in accordance with a quantity of electrostatic capacity and a surface potential of a target of static electricity removal is described, for example, in Japanese Patent Application Laid-open No. H11-345697 ([0010] to [0017], FIG. 1, etc.)

The static electricity removal device has at least one discharge electrode needle that causes corona discharge to occur on a target of static electricity removal by applying a voltage, a surface potentiometer that continuously measures a surface potential of the target of static electricity removal, an arithmetic processor that performs an arithmetic operation of a voltage to be applied so that the surface potential of the target of static electricity removal converges to zero in accordance with the measured surface potential, and a voltage output unit that outputs a voltage to be applied obtained by the arithmetic operation to the discharge electrode needle, and the static electricity removal device is configured so as to vary the voltage to be applied to the discharge electrode needle by feeding back the measurement result of the surface potentiometer to the arithmetic processor. The arithmetic processor also has a function of performing an arithmetic operation of electrostatic capacity of the target of static electricity removal based on variations in the measured values of the surface potential.

According to the conventional technology described in the above-mentioned patent application Laid-open No. H11-345697, the surface potential of the target of static electricity removal and the electrostatic capacity based thereon are measured at all times and the voltage to be applied to the discharge electrode needle is controlled by feeding back these measured values to the arithmetic processor, and thus it is possible to tentatively remove static electricity with high precision.

A manufacturing apparatus of a liquid crystal panel that prevents a liquid crystal substrate from being oppositely charged even when an ion balance is lowered by causing only the number of ions necessary for static electricity removal among ions generated by an ionizer (static electricity removal device) to reach the liquid crystal substrate (target of static electricity removal) is described in Japanese Patent No. 3522586 ([0015] to [0024], FIG. 1, etc.).

The liquid crystal panel manufacturing apparatus has a static electricity removal device that generates ions by corona discharge, and an electrode member, such as a grid electrode plate, which adjusts the number of ions directed toward the target of static electricity removal in accordance with an amount of electrostatic charge of the target of static electricity removal, wherein the static electricity removal device comprises a shield case the discharge side of which is open, a discharge electrode provided within the shield case, and a high voltage power supply that applies a high voltage necessary for corona discharge to the discharge electrode.

As its function, the fact is taken into consideration that an electric field between a liquid crystal substrate and an electrode member changes depending on an amount of electrostatic charge of the liquid crystal substrate, and when the amount of electrostatic charge is small, the electric field decreases in magnitude, and therefore, most of ions generated from the static electricity removal device are caused to escape from the electrode member to the ground side to reduce the number of ions that reach the liquid crystal substrate. When the amount of electrostatic charge is large, the electric field increases in magnitude, and therefore, most of ions generated from the static electricity removal device are caused to reach the liquid crystal substrate to enhance the static electricity removal effect.

However, in a conventional technology described in patent application Laid-open No. H11-345697, the static electricity removal device is controlled basically based on the surface potential of the target of static electricity removal and the ion balance between positive and negative ions generated from the static electricity removal device is not taken into consideration. Because of this, there may be the case where the numbers of positive and negative ions generated from the static electricity removal device are not balanced and the target of static electricity removal originally not charged may be charged to one of the positive and negative polarities by the ionizer. Even if the target of static electricity removal becomes charged in this manner, it is possible to remove static electricity by the control based on the surface potential by the static electricity removal device. However, a static electricity removing operation not required originally needs to be carried out and thus more time and power are required.

In the prior art described in Japanese Patent No. 3522586, the number of ions that reach the liquid crystal substrate is controlled in accordance with the electric field strength corresponding to the amount of electrostatic charge of the liquid crystal substrate, and therefore, there is a limit in improving precision of the static electricity removal, and for example, it is difficult to maintain the liquid crystal substrate precisely at ±0 [V].

Since it is necessary to provide a large-sized grid electrode plate etc. in order to cover a space between a plurality of discharge electrode needles arranged in the static electricity removal device and the liquid crystal substrate, there is a problem in that components are upsized, and therefore, the entire device is upsized and its cost is raised.

An object of the present invention is therefore to provide an ion control sensor at a low cost, which improves the performance of a static electricity removal device by making it possible to detect an ion balance and a charged potential of a target of static electricity removal with a remarkably simple configuration.

### DISCLOSURE OF THE INVENTION

To solve the above problems, as described in claim 1, the present invention provides an ion control sensor in a static electricity removal device that removes static electricity by supplying positive and negative ions to a target of static electricity removal, the static electricity removal device comprising a surface potential measuring probe that measures a surface potential of the target of static electricity removal, the sensor comprising a potential detector that constitutes the surface potential measuring probe and a conductive cap placed so as to surround the potential detector via an insulating member.

Furthermore, as described in claim 2, the present invention provides the ion control sensor wherein a potential generated in the cap by charges of the target of static electricity removal or ions supplied from the static electricity removal device is detected by the potential detector and is sent out to a control circuit within the static electricity removal device as a feedback signal.

With the above configuration, the present invention realizes a static electricity removal device with high precision and high efficiency, capable of detecting an ion balance between positive and negative ions generated by the static electricity removal device and a surface potential of a target of static electricity removal using a single ion control sensor.

Further, the present invention can be achieved only by attaching a conductive cap to a potential detector of an existing surface potential measuring probe via an insulating member and can be provided at a low cost with a remarkably simple configuration.

### BRIEF DESCRIPTION OF THE DRAWINGS

FIG. 1 is a perspective view of an ion control sensor according to a preferred embodiment of the present invention.

FIG. 2 is an explanatory diagram of a state where the ion control sensor according to the preferred embodiment is in use.

FIG. 3 is a schematic configuration diagram of a static electricity removal device as shown in FIG. 2.

### BEST MODES FOR CARRYING OUT THE INVENTION

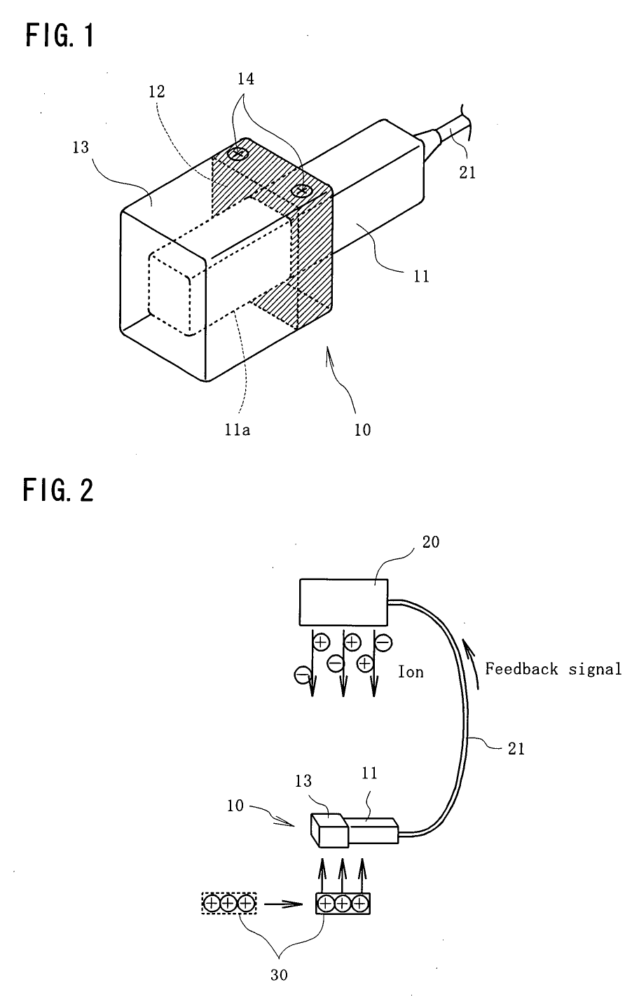

Best modes for carrying out the present invention will be explained below with reference to the drawings. FIG. 1 is a perspective view of an ion control sensor 10 according to an embodiment.

In FIG. 1, reference number 11 denotes a rectangular rod-like surface potential measuring probe, such as a so-called tuning fork-type or vibrating reed-type surface potential measuring apparatus. This probe 11 is capable of measuring a surface potential of a target of static electricity removal without contact. The principle of surface potential measurement by the probe 11 is not limited in particular. The probe 11 is connected to a static electricity removal device 20, to be described later, via a cable 21.

Substantially at the center of the surface potential measuring probe 11 in the longitudinal direction, a hollow square-shaped insulating member 12 made of synthetic resin etc. is fixed and a bottomed rectangle-cylindrical cap 13 made of conductive material is attached with screws 14 so as to surround the insulating member 12 and the top end of the probe 11. The top end of the probe 11 constitutes a potential detector 11a having a detection hole (not shown) and the potential detector 11a and the inner surface of the cap 13 are kept in a non-contact state by the insulating member 12 and a space.

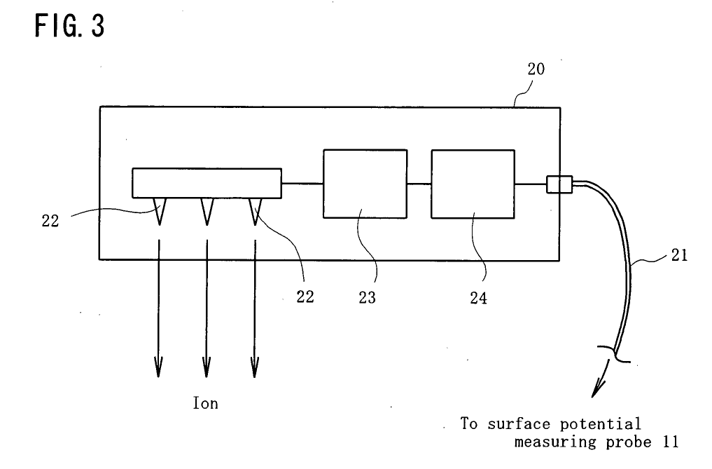

FIG. 2 is an explanatory diagram of a state where the ion control sensor according to the present embodiment is in use and FIG. 3 is a schematic configuration diagram of the static electricity removal device 20.

As shown in FIG. 3, the static electricity removal device 20 comprises a plurality of discharge electrodes 22 that generate positive and negative ions by corona discharge, a high voltage power supply circuit 23 that applies a variable high voltage to the discharge electrodes 22, and a control circuit 24 that controls the high voltage power supply circuit 23 based on an output signal of the surface potential measuring probe 11.

The static electricity removal device 20 can be either an ac-powered static electricity removal device that applies an alternating current voltage to the discharge electrodes 22 or a dc-powered static electricity removal device that applies a direct current voltage. As the need arises, it can comprise a fan that forcibly sends generated ions toward a target of static electricity removal.

The function of the ion control sensor according to the present embodiment is explained next with reference to FIG. 2.

In FIG. 2, the ion control sensor 10 is placed close to the surface of a target of static electricity removal 30 from which static electricity is removed. The target of static electricity removal 30 can be various targets of static electricity removal including a semiconductor wafer, a liquid crystal substrate, etc.

When it is assumed that the target of static electricity removal 30 conveyed immediately under the ion control sensor 10 is positively charged, the cap of the ion control sensor 10 also becomes positively charged due to electrostatic induction. The positive potential is detected by the potential detector 11a of the surface potential measuring probe 11 and its detection signal is input to the control circuit 24 within the static electricity removal device 20 as a feedback signal.

Due to this, the control circuit 24 causes the high voltage power supply circuit 23 to operate to generate a number of negative ions from the discharge electrode 22 to remove (neutralize) the positive potential of the target of static electricity removal 30. For example, the control circuit 24 carries out a control operation to make the amplitude of the alternating current or direct current negative voltage to be applied to the discharge electrodes 22 greater than the amplitude of the positive voltage.

Due to the above-mentioned operation, since a number of the negative ions generated from the discharge electrodes 22 are supplied to the target of static electricity removal 30, the positive potential of the target of static electricity removal 30 is neutralized and thus its static electricity is removed.

When a balance between the numbers of positive and negative ions generated from the discharge electrodes 22, that is, a so-called ion balance is detected, the static electricity removal device 20 is operated in a state where the target of static electricity removal 30 is not located immediately under the ion control sensor 10 or in a state where the target of static electricity removal 30 is not positively or negatively charged even if it is present.

In this case, the cap 13 of the ion control sensor 10 becomes positively or negatively charged in accordance with the balance between the numbers of positive and negative ions generated from the discharge electrodes 22. When a well ion balance is maintained, the potential will be zero.

In other words, when the generated positive ions are more than the negative ions, the cap 13 becomes positively charged, and therefore, the potential detector 11a of the surface potential measuring probe 11 detects a positive potential and its detection signal is input to the control circuit 24 within the static electricity removal device 20 as a feedback signal. Because of this, the control circuit 24 carries out a control operation to cause the high voltage power supply circuit 23 to operate so that a number of negative ions are generated from the discharge electrodes 22.

It is obvious that when the negative ions generated from the discharge electrodes 22 are more than the positive ions, an inverse operation of the above operation is carried out.

The above embodiment is only an example and the shape and configuration of the ion control sensor or the surface potential measuring probe of the present invention are not limited in any way and various modifications can be made.

The configuration and shape of the static electricity removal device are also not limited in particular, and the present invention is applicable to various types of static electricity removal devices, such as a ceiling attachment type, desktop type, and air-gun type.

1. An ion control sensor in a static electricity removal device that removes electricity by supplying positive and negative ions to a target of static electricity removal, the static electricity removal device comprising a surface potential measuring probe that measures a surface potential of the target of static electricity removal,
the sensor comprising a potential detector that constitutes the surface potential measuring probe and a conductive cap placed so as to surround the potential detector via an insulating member.

2. The ion control sensor according to claim 1, wherein a potential generated in the cap by charges of the target of static electricity removal or ions supplied from the static electricity removal device is detected by the potential detector and is sent out to a control circuit within the static electricity removal device as a feedback signal.
